(19) United States
(12) Patent Application Publication
(10) Pub. No.: US 2024/0368765 A1
(43) Pub. Date: Nov. 7, 2024

(54) SUBSTRATE PROCESSING APPARATUS, METHOD OF TEMPERATURE MEASURING, AND METHOD OF TEMPERATURE CONTROLLING

(71) Applicant: JUSUNG ENGINEERING CO., LTD., Gwangju-si, Gyeonggi-do (KR)

(72) Inventors: Oh Hyeon KWON, Yongin-si Gyeonggi-do (KR); In Woo BACK, Yongin-si Gyeonggi-do (KR)

(21) Appl. No.: 18/556,661

(22) PCT Filed: Mar. 31, 2022
(86) PCT No.: PCT/KR2022/004645

§ 371 Date: Oct. 20, 2023

(30) Foreign Application Priority Data
Apr. 20, 2021 (KR) 10-2021-0050898

(51) Int. Cl. C23C 16/46; C23C 16/458

(52) U.S. Cl. CPC C23C 16/46; C23C 16/4586

(57) ABSTRACT

Disclosed are a substrate processing apparatus, a temperature measurement method and a temperature control method. The substrate processing apparatus includes a chamber, a susceptor configured such that a substrate is placeable thereon, a heater unit configured to heat the susceptor, a temperature measurement unit configured to measure temperatures of the substrate, and a controller configured to control the heater unit using the temperatures of the substrate, and the temperature measurement unit includes a first measurement unit configured to measure temperatures of the substrate inside the chamber, a second measurement unit configured to measure temperatures of the substrate outside the chamber, a storage unit configured to store first data measured by the first measurement unit, second data measured by the second measurement unit, and third data calculated using the first data and the second data, and a determiner configured to calculate temperatures of the substrate using the third data.

### FIELD OF THE INVENTIVE CONCEPT

The present inventive concept relates to a substrate processing apparatus, a temperature measurement method and a temperature control method, and more particularly to a method which calculates the temperatures of a substrate inside a chamber by measuring the temperatures of the substrate discharged from the chamber and reflecting correction values, stored in advance, in the measured temperatures, and controls a unit configured to heat the substrate.

### BACKGROUND

In general, in order to manufacture a semiconductor element, a display device and a thin film solar cell, a thin film deposition process in which a thin film formed of a specific material is formed on a substrate, a photolithography process in which selected regions of the thin film are exposed or shielded using a photosensitive material, and an etching process in which the thin film is removed from the selected regions by patterning are performed. Thereamong, the thin film deposition process and the etching process are performed in a substrate processing apparatus which is optimized under a vacuum state.

In the substrate processing apparatus which is optimized under the vacuum state, the substrate is heated using a heating unit, and the thin film deposition process or the etching process are performed by supplying process gas into the reaction space of a chamber. In a substrate processing process, the temperature of the substrate affects the quality of a product, and thus, the temperature of the substrate should be accurately measured.

In general, the temperature of the substrate is measured using a non-contact temperature measurement device, such as an optical thermometer. When the optical thermometer undergoes the process for a long time, foreign substances produced due to reaction of the process gas during the substrate processing process may be accumulated on the optical thermometer. When the foreign substances are accumulated on the temperature measurement device, it is difficult to accurately measure the temperature of the substrate. Therefore, an apparatus and method for accurately measuring the temperature of a substrate are required.

### SUMMARY

Accordingly, the present inventive concept is directed to a substrate processing apparatus, a temperature measurement method and a temperature control method that substantially obviate one or more problems due to limitations and disadvantages of the related art.

An object of the present inventive concept is to provide a substrate processing apparatus, a temperature measurement method and a temperature control method, in which the temperatures of a substrate inside a chamber may be accurately measured, and thus the temperature of the entire substrate may be controlled.

Additional advantages, objects, and features of the invention will be set forth in part in the description which follows and in part will become apparent to those having ordinary skill in the art upon examination of the following, or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a substrate processing apparatus includes a chamber configured to provide a processing space, a susceptor configured such that a substrate is placeable thereon, a heater unit configured to heat the susceptor, a temperature measurement unit configured to measure temperatures of the substrate, and a controller configured to control the heater unit using the temperatures of the substrate, wherein the temperature measurement unit includes a first measurement unit configured to measure temperatures of the substrate inside the chamber, a second measurement unit configured to measure temperatures of the substrate outside the chamber, a storage unit configured to store first data measured by the first measurement unit, second data measured by the second measurement unit, and third data calculated using the first data and the second data, and a determiner configured to calculate temperatures of the substrate using the third data.

The third data may include difference values between the first data and the second data.

The determiner may calculate the temperatures of the substrate by adding the third data to the second data.

The second measurement unit may be disposed on a slot valve.

The second measurement unit may include a plurality of temperature measurement devices.

In another aspect of the present inventive concept, a temperature measurement method includes taking a substrate placed inside a chamber out of the chamber, measuring temperatures of the substrate outside the chamber, and determining temperatures of the substrate by reflecting correction values, stored in advance, in the temperatures of the substrate measured outside the chamber.

In the measuring the temperatures of the substrate outside the chamber, the temperatures of the substrate may be measured around a slot valve.

The correction values may be generated by storing first data acquired by measuring temperatures of another substrate inside the chamber, storing second data acquired by measuring temperatures of the substrate outside the chamber, and storing third data calculated using the first data and the second data as the correction values necessary for temperature measurement.

The third data may be calculated as difference values between the first data and the second data.

In yet another aspect of the present inventive concept, a temperature control method controls a temperature of a unit configured to heat the substrate using the temperatures of the substrate determined using the temperature measurement method.

### Effect

The substrate processing apparatus, method of temperature measuring, and method of temperature controlling according to the present inventive concept can make the temperature of the entire substrate uniform by accurately measuring the temperature of the substrate inside the chamber and controlling the means for heating the substrate.

### BRIEF DESCRIPTION OF THE DRAWINGS

FIG. 1 is a diagram schematically illustrating some elements of a substrate processing apparatus according to the present inventive concept;

FIG. 2 is a block diagram schematically illustrating the configuration of the substrate processing apparatus according to the present inventive concept;

FIG. 3 is a flowchart representing a process of generating correction values for a temperature measurement method according to the present inventive concept;

FIG. 4 is a flowchart representing a process of generating first data shown of FIG. 3 according to the present inventive concept;

FIG. 5 is a flowchart representing a process of generating second data of FIG. 3 according to the present inventive concept; and

FIG. 6 is a flowchart representing the temperature measurement method and a temperature control method according to the present inventive concept.

### DETAILED DESCRIPTION

Specific structural or functional descriptions in embodiments of the present inventive concept set forth in the description which follows will be exemplarily given to describe the embodiments of the present inventive concept, and the embodiments of the present inventive concept are not limited to the aspects disclosed herein but may be implemented in various different forms.

The present inventive concept may be variously modified and be implemented in various forms, and thus, specific embodiments, examples of which are illustrated in the accompanying drawings, will be described in detail in the following description. However, the present inventive concept should not be interpreted as being limited to the embodiments set forth herein, and it will be understood that the present inventive concept covers modifications, equivalents or alternatives which come within the scope and technical range of the invention.

In the following description of the embodiments, terms, such as “first” and “second”, are used only to describe various elements, and these elements should not be construed as being limited by these terms. These terms are used only to distinguish one element from other elements. For example, a first element described hereinafter may be termed a second element, and similarly, a second element described hereinafter may be termed a first element, without departing from the scope of the invention.

When an element or layer is referred to as being “connected to” or “coupled to” another element or layer, it may be directly connected or coupled to the other element or layer, or intervening elements or layers may be present. In contrast, when an element or layer is referred to as being “directly connected to” or “directly coupled to” another element or layer, there may be no intervening elements or layers present. Other words used to describe relationships between elements should be interpreted in a like fashion, e.g., “between” versus “directly between,” “adjacent” versus “directly adjacent,” etc.

The terminology used herein is for the purpose of describing particular embodiments only and is not intended to be limiting. As used herein, singular forms may be intended to include plural forms as well, unless the context clearly indicates otherwise. The terms “comprises,” “comprising,” “including,” and “having” are inclusive and therefore specify the presence of stated features, integers, steps, operations, elements, components, and/or combinations thereof, but do not preclude the presence or addition of one or more other features, integers, steps, operations, elements, components, and/or combinations thereof.

Unless defined otherwise, all terms including technical or scientific terms used in the following description have the same meanings as those of terms generally understood by those skilled in the art. Terms defined in generally used dictionaries will be interpreted as having meanings coinciding with contextual meanings in the related technology, and are not to be interpreted as having ideal or excessively formal meanings unless defined clearly in the description.

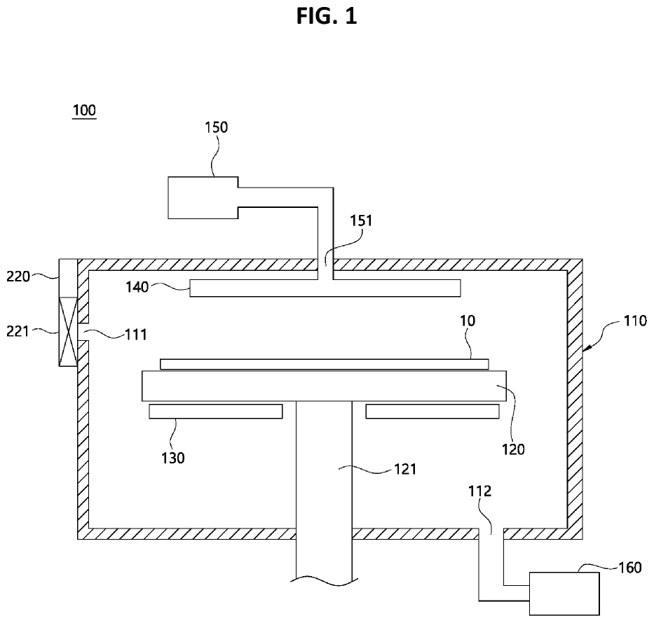

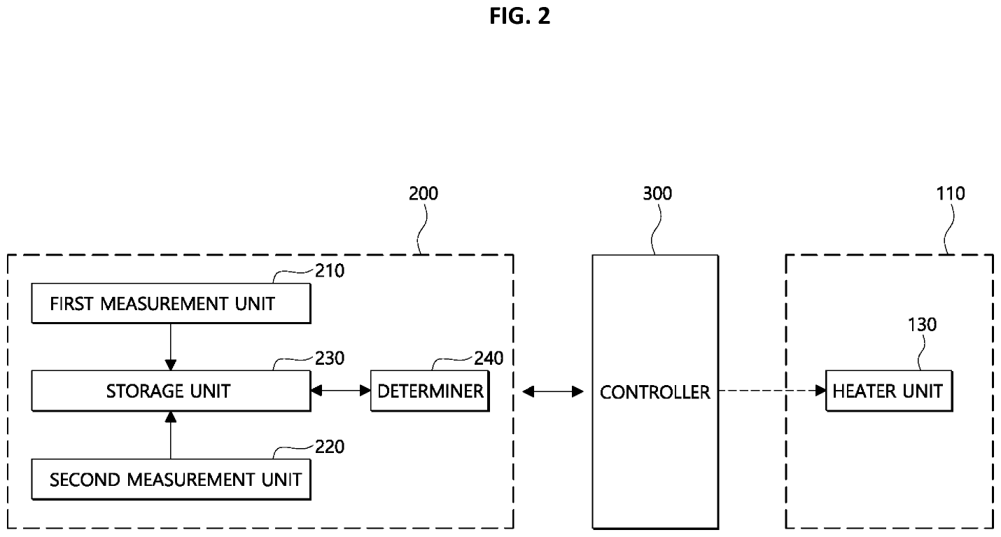

Hereinafter, a substrate processing apparatus, a temperature measurement method and a temperature control method according to the present inventive concept will be described with reference to the accompanying drawings. FIG. 1 is a diagram schematically illustrating some elements of the substrate processing apparatus according to the present inventive concept, and FIG. 2 is a block diagram schematically illustrating the configuration of the substrate processing apparatus according to the present inventive concept.

A substrate processing apparatus 100 according to one embodiment of the present inventive concept may include a chamber 110 provided with a reaction space formed therein, a susceptor 120 provided in the chamber 110 and configured to support at least one substrate 100, a heater unit 130 provided under the susceptor 120 and configured to heat the susceptor 120, a gas distributer 140 provided at one side of the inside of the chamber 110 so as to face the susceptor 120 and configured to inject process gas, a gas supplier 150 provided outside the chamber 110 and configured to supply the process gas to the gas distributer 140, and an exhauster 160 configured to exhaust gas in the chamber 110.

The chamber 110 may be provided in a vessel type configured such that a space for a deposition process on the substrate 10 is formed therein. The chamber 110 may be provided in various shapes depending on the shape of the substrate 10. Here, the substrate 10 may employ a silicon substrate used to manufacture semiconductors or a glass substrate used to manufacture flat panel displays. That is, when the substrate 10, such as a silicon substrate, is circular, the chamber 110 may be provided in a cylindrical shape having a circular cross-section and, when the substrate 10, such as a glass substrate, is rectangular, the chamber 110 may be provided in a hexahedral shape having a rectangular cross-section.

The susceptor 120 and the gas distributer 140 may be provided so as to face each other inside the chamber 110. For example, the susceptor 120 may be provided in the lower region of the chamber 110, and the gas distributer 140 may be provided in the upper region of the chamber 110. Further, a substrate entrance 111 through which the substrate 10 enters and exits the chamber 110 may be provided at one side of the chamber 110. A gas inlet 151 connected to the gas supplier 150 configured to supply process gas to the inside of the chamber 110 may be provided in the chamber 110.

Further, the exhauster 160 may be connected to an exhaust port 112 provided in the lower portion of the chamber 110 so as to adjust the internal pressure of the chamber 110 or to exhaust the process gas or other foreign substances in the chamber 110.

For example, the substrate entrance 111 may be provided in one side surface of the chamber 110 so as to have a size sufficient to enable the substrate 10 to enter and exit the chamber 110 through the substrate entrance 111, the gas inlet 151 may be formed through the upper wall of the chamber 110, and the exhaust port 112 may be formed through the lower wall of the chamber 110 located at a lower position than the susceptor 120.

The susceptor 120 is provided inside the chamber 110, and at least one substrate 100 having entered into the chamber 100 is placed on the susceptor 120. The susceptor 120 is provided at a position facing the gas distributer 140. For example, the susceptor 120 may be provided in the lower region of the inside of the chamber 110, and the gas distributer 140 may be provided in the upper region of the inside of the chamber 110.

The susceptor 120 may be provided with, for example, an electrostatic chuck, so as to maintain adsorption of the substrate 10 thereto using electrostatic force to support the substrate 10 placed on the susceptor 120, or may support the substrate 10 using vacuum adsorption or mechanical force. Further, the susceptor 120 may be provided in a planar shape corresponding to the shape of the substrate 10, for example, in a circular shape or a rectangular shape, and may have a greater size than the substrate 10.

An elevating device 121 configured to move the susceptor 120 up and down may be provided under the susceptor 120. The elevating device 121 may be provided to support at least one region of the susceptor 120, for example, the central part of the susceptor 120, and moves the susceptor 120 so as to come closer to the gas distributer 140 when the substrate 10 is placed on the susceptor 120.

Of course, the heater unit 130 may be mounted under or in the susceptor 120. The heater unit 130 may generate heat of a predetermined temperature so as to heat the substrate 10, thereby allowing a thin film deposition and stacking process, an etching process, etc. to be easily performed on the substrate 10. A coolant supply path (not shown) may be provided in the susceptor 120, and a coolant may be supplied through the coolant supply path so as to lower the temperature of the substrate 10.

The gas distributer 140 is provided in the upper region of the inside of the chamber 110, and injects process gas towards the substrate 10 placed on the susceptor 120. The gas distributer 140 may be provided in a shape corresponding to the shape of the substrate 10 in the same manner as the susceptor 120, for example, in a circular shape or a rectangular shape.

A slot valve 221 is disposed outside the chamber 110 around the substrate entrance 111 formed thereon, and a second measurement unit 220 is located on the slot valve 221. The second measurement unit 220 may include a plurality of optical thermometers. The second measurement unit 220 may measure the surface temperatures of a plurality of regions of the substrate 10 when the substrate 10 is taken out of the chamber 110.

The substrate processing apparatus 100 according to the present inventive concept further includes, in addition to the chamber 110 shown in FIG. 1, a temperature measurement unit 200 and a controller 300, as shown in FIG. 2. The temperature measurement unit 200 includes a first measurement unit 210 configured to measure temperatures of the substrate 10 inside the chamber 110, the second measurement unit 220 configured to measure temperatures of the substrate 10 outside the chamber 110, a storage unit 230 configured to store first data measured by the first measurement unit 210, second data measured by the second measurement unit 220, and third data calculated using the first data and the second data, and a determiner 240 configured to calculate temperatures of the substrate using the third data.

The first measurement unit 210 measures the temperature of the substrate 10 under the condition that the substrate 10 is disposed inside the chamber 110, and the second measurement unit 220 is disposed at the upper end of the slot valve 221 and measures the surface temperatures of the substrate 10 when the substrate 10 is taken out of the chamber 110.

In the following description, temperature data of the substrate 10 measured by the first measurement unit 210 and temperature data of the substrate 10 measured by the second measurement unit 220 are referred to as “first data” and “second data”, respectively. The first data and the second data are stored in the storage unit 230. The determiner 240 of the temperature measurement unit 200 calculates the third data using the first data and the second data stored in the storage unit 230. The third data may include difference values between the first data and the second data. The third data calculated by the determiner 240 and stored in the storage unit 230 is referred to as “correction values” in the following description.

The controller 300 controls the heater unit 130 inside the chamber 110 using the correction values.

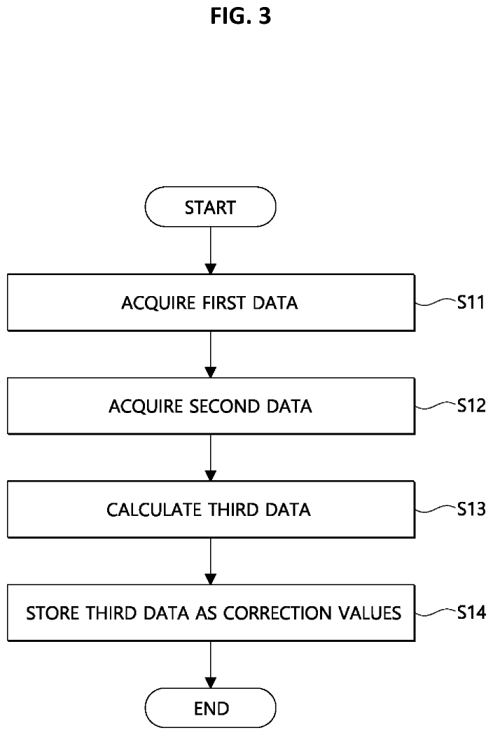

The temperature measurement method according to the preset invention is executed after such temperature correction values are set in advance, and a process of setting the temperature correction values is shown in FIG. 3. As shown in FIG. 3, the process includes acquiring first data by measuring the temperatures of a substrate inside the chamber (S11), acquiring second data by measuring the temperatures of the substrate outside the chamber (S12), calculating third data using the first data and the second data (S13), and storing the third data as correction values (i.e., temperature correction values).

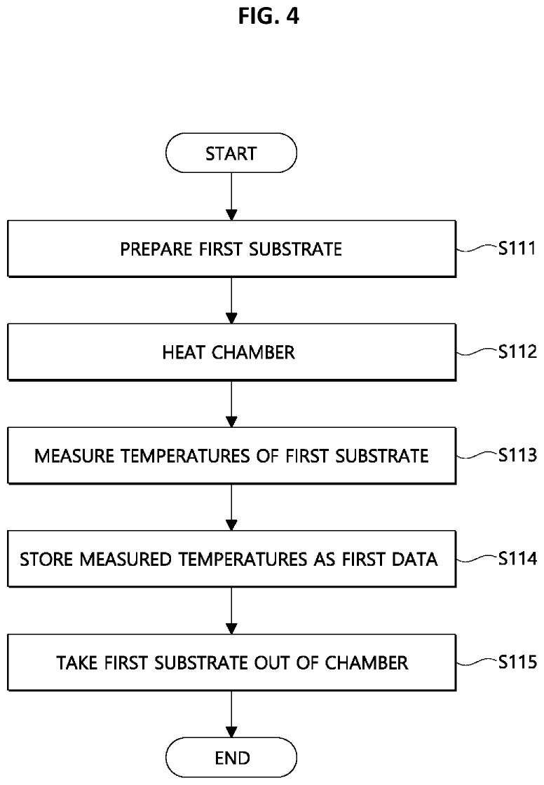

The acquisition of the first data (S11) is performed through a process shown in FIG. 4. First, a first substrate is placed on the susceptor 120. A thermocouple (TC) wafer may be used as the first substrate. The TC wafer indicates a wafer used to acquire temperature data by measuring the temperatures of specific positions of the wafer in the chamber. A plurality of holes is formed in the wafer to a designated depth, thermocouples are disposed in the holes, and the thermocouples measure temperatures due to thermal resistance.

The thermocouples disposed in the first substrate so as to measure the surface temperatures of a plurality of regions of the substrate correspond to the first measurement unit 210 of FIG. 2. Further, the first measurement unit 210 may be implemented as including temperature measurement devices provided above the chamber so as to measure the temperatures of the substrate, in addition to use of the TC wafer as the first substrate. For example, the first measurement unit 120 may be implemented as including non-contact temperature measurement devices, such as optical thermometers, which are disposed at positions adjacent to the gas distributer 140 provided in the upper region of the inside of the chamber 110 so as to measure the temperatures of the substrate.

The TC wafer is disposed on the susceptor 120 in the chamber 110 under the same conditions as a substrate manufacturing process, and will thus be referred to as a substrate (S111).

The chamber 110 is heated to a designated temperature, and then, the temperature of the chamber 110 is stabilized (S112).

Under the condition that the temperature of the chamber 110 is stabilized, the temperatures of the first substrate are measured using the first measurement unit 210 (S113).

The temperature information of the substrate measured by the first measurement unit 210 is stored in the storage unit 230 as first data. For example, on the assumption that the temperatures of four regions obtained by dividing the substrate into a 2×2 matrix are measured, data measured by the first measurement unit 210 is stored in the storage unit 230 as the values of TP₁₁ to TP₂₂, as follows (S114).

$$[ \begin{matrix}T {P}_{11} & T {P}_{12} \\ T {P}_{21} & T {P}_{22}\end{matrix} ]$$

When temperature measurement has been completed, the chamber 110 stands by until the temperature of the chamber 110 is cooled to room temperature and, when the temperature of the chamber 110 is stabilized, the first substrate is taken out of the chamber 110 (S115). Thereby, the process of generating the first data has been completed.

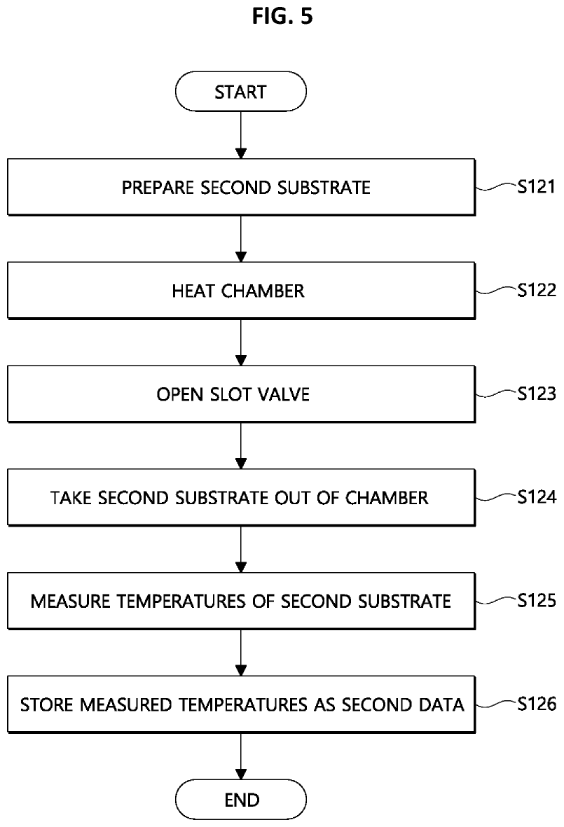

Further, the acquisition of the second data (S12) is performed through a process shown in FIG. 5. First, a second substrate is disposed on the susceptor 120 inside the chamber 110. Here, the second substrate indicates a substrate configured to generate the second data necessary to calculate the correction values and, in the same manner as the first substrate, the second substrate is disposed on the susceptor 120 in the chamber 110 under the same conditions as the substrate manufacturing process, and will thus be referred to as a substrate. The first data may be generated by measuring the temperatures of the first substrate using the first measurement unit, and the second data may be generated using the second measurement unit (S121).

The chamber 110 is heated to a temperature necessary for the process, and then, the temperature of the chamber 110 is stabilized (S122).

Under the condition that the temperature of the chamber 110 is stabilized, the substrate on the susceptor 120 is lifted up, and then, the slot valve 221 disposed at one side of the chamber 110 is opened (S123).

The substrate is taken out of the chamber 110 using a vacuum robot through the substrate entrance 111 opened by the slot valve 221. The temperature of the substrate is lowered due to lift-up of the substrate from the susceptor 120, opening of the substrate entrance 111 by the slot valve 221 and movement of the substrate using the vacuum robot (not shown) (S124).

The temperatures of the substrate are measured by the second measurement unit 220 disposed on the upper surface of the slot valve 221 while taking the substrate out of the chamber 110. The second measurement unit 220 may include a plurality of optical thermometers, and a measurement operation cycle may be determined in consideration of a time for the substrate to be moved to the outside of the chamber 110. For example, when the second measurement unit 220 includes two optical thermometers, in order to measure the temperatures of four regions obtained by dividing the substrate into a 2×2 matrix, the second measurement unit 220 may measure the temperatures of the substrate in a direction of movement of the substrate to the outside of the chamber 110. That is, the second measurement unit 220 may measure the temperatures of first points at a first point in time, and measure the temperatures of second points at a second point in time, during a process of taking the substrate out of the chamber 110 (125).

Temperature information of a plurality of regions of the substrate measured by the second measurement unit 220 may be stored in the storage unit 230 as the second data. In the same manner as the first data, the temperature data, acquired by measuring the temperatures of the four regions into which the substrate is divided, is stored as the values of TR₁₁ to TR₂₂, as follows (S126), and thereby, the process of generating the second data has been completed.

$$[ \begin{matrix}T {R}_{11} & T {R}_{12} \\ T {R}_{21} & T {R}_{22}\end{matrix} ]$$

The determiner 240 of the temperature measurement unit 200 calculates the third data using the first data and the second data, generated through the above-described processes. The third data may include difference values between the first data and the second data.

$$[ \begin{matrix}T {P}_{11} & T {P}_{12} \\ T {P}_{21} & T {P}_{22}\end{matrix} ] - [ \begin{matrix}T {R}_{11} & T {R}_{12} \\ T {R}_{21} & T {R}_{22}\end{matrix} ] = [ \begin{matrix}Δ {t}_{11} & Δ {t}_{12} \\ Δ {t}_{21} & Δ {t}_{22}\end{matrix} ]$$

The determiner 240 of the temperature measurement unit 200 stores the third data as correction values.

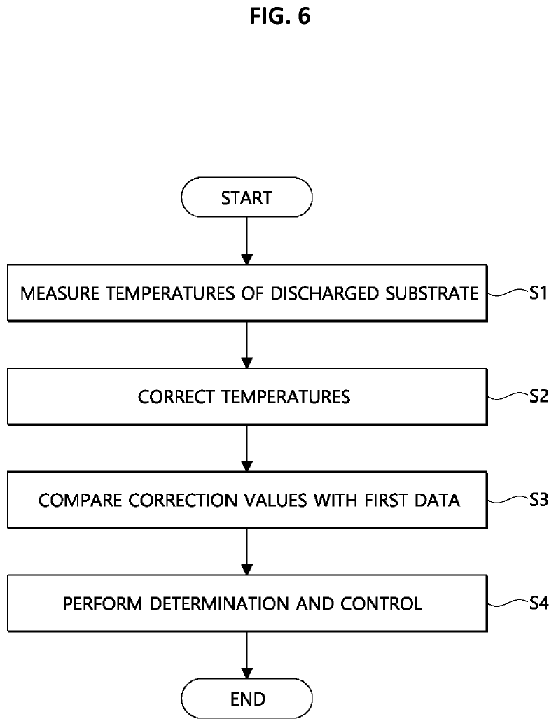

After the above-described processes for pre-processing data so as to calculate the correction values are performed, the temperature measurement method and the temperature control method are executed, as shown in FIG. 6.

After a substrate 10 is placed on the susceptor 120, the chamber 110 is heated so that the internal temperature of the chamber 110 may be increased. Here, the substrate 10 indicates a substrate used in the substrate processing process. Under the condition that the internal temperature of the chamber 110 is stabilized, the substrate 10 on the susceptor 120 is lifted up, and the slot valve 221 disposed at one side of the chamber 110 is opened. The temperatures of the substrate 10 are measured by the second measurement unit 220 disposed at the upper end of the slot valve 221 while taking the substrate 10 out of the chamber 110 using the vacuum robot through the open slot valve 221. The second measurement unit 220 including the plurality of optical thermometers measures the temperatures of a plurality of regions of the substrate 100. Such an operation is performed in the same manner as in the process of generating the second data. The temperature data TS₁₁ to TS₂₂ of the substrate 100 taken out of the chamber 110 may be stored in a memory (S1).

$$[ \begin{matrix}T {S}_{11} & T {S}_{12} \\ T {S}_{21} & T {S}_{22}\end{matrix} ]$$

When temperature measurement of the substrate 10 has been completed while transferring the substrate 10 to the outside of the chamber 110, the controller 300 reads the correction values stored in the storage unit 230. The controller 30 may calculate temperature values TSᵢ₁₁ to TSᵢ₂₂ of the substrate 10, which may be estimated as temperatures of the substrate 10 when the substrate 10 is located inside the chamber 110, by adding the correction values to the temperature data of the substrate 10 stored in the memory (S2).

$$[ \begin{matrix}T {S}_{11} & T {S}_{12} \\ T {S}_{21} & T {S}_{22}\end{matrix} ] + [ \begin{matrix}Δ {t}_{11} & Δ {t}_{12} \\ Δ {t}_{21} & Δ {t}_{22}\end{matrix} ] = [ \begin{matrix}T {S}_{i 11} & T {S}_{i 12} \\ T {S}_{i 21} & T {S}_{i 22}\end{matrix} ]$$

Thereafter, the controller 300 determines uniformity in the temperature data of the respective regions of the substrate 10. The controller 300 confirms whether or not temperature differences among the respective regions of the substrate 10 are within an error range. The controller 300 compares the temperature values TSᵢ₁₁ to TSᵢ₂₂, calculated by reflecting the correction values, with the first data TP₁₁ to TP₂₂, i.e., the temperature values measured using the TC wafer. For example, the controller 300 may compare two temperature values TP₁₁ and TS₁₁, TP₁₂ and TSᵢ₁₂, TP₂₁ and TSᵢ₂₁, and TP₂₂ and TSᵢ₂₂, each of which correspond to the same position of the substrate 10, with each other. Alternatively, the controller 300 may calculate the average value AVR_{TSi} of the temperature values TSᵢ₁₁ to TSᵢ₂₂, and may determine whether or not a difference between each of the temperature values TSᵢ₁₁ to TS₁₂₂ of the respective regions of the substrate 10 and the average value AVR_{TSi} deviates from a designated range. Here, the designated range may be set depending on the material of the substrate 10, the purpose of the substrate 10, the size of the substrate 10, the deposition conditions of the chamber 110, etc. (S3).

The controller 300 may determine uniformity in the temperatures and distribution in the temperatures depending on a result of the comparison, and may calculate temperature compensation values for controlling the heater unit 130 using the uniformity in the temperatures. For example, in case that the temperature value TSᵢ₁₁ is lower than the average value AVR_{TSi} by 10° C., the controller 130 may set the temperature compensation value of the heater unit 130 for heating the susceptor 120 under the corresponding region of the substrate 10 to 10° C. Through the above control, the temperature of the entire substrate 10 (S4) may be uniformized.

As described above, in the temperature control method according to the present inventive concept, the temperature correction values may be calculated in advance and stored, temperatures of a substrate may be measured while the substrate is taken out of the chamber, temperatures of the substrate when the substrate is located inside the chamber may be calculated by reflecting the temperature correction values in the measured temperatures of the substrate, and the heater unit configured to heat the substrate may be controlled using the estimated temperatures of the substrate, thereby being capable of compensating for the temperatures of the substrate so as to uniformize the temperature of the entire substrate.

As is apparent from the above description, a substrate temperature control apparatus and method according to the present inventive concept may accurately measure temperatures of a substrate inside a chamber, and may control a heater unit configured to heat the substrate based on the measured temperatures, thereby being capable of uniformizing the temperature of the entire substrate.

It will be apparent to those skilled in the art that various modifications and variations can be made in the present inventive concept without departing from the spirit or scope of the invention. Thus, it is intended that the present inventive concept cover the modifications and variations of this invention provided they come within the scope of the appended claims and their equivalents.

1. A substrate processing apparatus comprising:
a chamber configured to provide a processing space;
a susceptor configured such that a substrate is placeable thereon;
a heater unit configured to heat the susceptor;
a temperature measurement unit configured to measure temperatures of the substrate; and
a controller configured to control the heater unit using the temperatures of the substrate,
wherein the temperature measurement unit comprises:
a first measurement unit configured to measure temperatures of the substrate inside the chamber;
a second measurement unit configured to measure temperatures of the substrate outside the chamber;
a storage unit configured to store first data measured by the first measurement unit, second data measured by the second measurement unit, and third data calculated using the first data and the second data; and
a determiner configured to calculate temperatures of the substrate using the third data.

2. The substrate processing apparatus according to claim 1, wherein the third data comprises difference values between the first data and the second data.

3. The substrate processing apparatus according to claim 2, wherein the determiner calculates the temperatures of the substrate by adding the third data to the second data.

4. The substrate processing apparatus according to claim 1, wherein the second measurement unit is disposed on a slot valve.

5. The substrate processing apparatus according to claim 4, wherein the second measurement unit comprises a plurality of temperature measurement devices.

6. A temperature measurement method comprising:
taking a substrate placed inside a chamber out of the chamber;
measuring temperatures of the substrate outside the chamber; and
determining temperatures of the substrate by reflecting correction values, stored in advance, in the temperatures of the substrate measured outside the chamber.

7. The temperature measurement method according to claim 6, wherein, in the measuring the temperatures of the substrate outside the chamber, the temperatures of the substrate is measured around a slot valve.

8. The temperature measurement method according to claim 6, wherein the correction values are generated by:
storing first data acquired by measuring temperatures of another substrate inside the chamber;
storing second data acquired by measuring temperatures of the substrate outside the chamber; and
storing third data calculated using the first data and the second data as the correction values necessary for temperature measurement.

9. The temperature measurement method according to claim 8, wherein the third data comprises difference values between the first data and the second data.

10. A temperature control method for controlling a temperature of a unit configured to heat the substrate using the temperatures of the substrate determined using the temperature measurement method according to claim 9.
